(19) United States
(12) Patent Application Publication
(10) Pub. No.: US 2010/0072453 A1
(43) Pub. Date: Mar. 25, 2010

(54) Phase-Changeable Fuse Elements and Memory Devices Containing Phase-Changeable Fuse Elements and Memory Cells Therein

(76) Inventors: Hong-sik Jeong, Gyeonggi-do (KR); Gi-tae Jeong, Seoul (KR); Kyung-chang Ryoo, Gyeonggi-do (KR); Hyeong-jun Kim, Seoul (KR)

Correspondence Address: MYERS BIGEL SIBLEY & SAJOVEC, PO BOX 37428, RALEIGH, NC, 27627, US

(21) Appl. No.: 12/492,275

(22) Filed: Jun. 26, 2009

(30) Foreign Application Priority Data
Jul. 23, 2008 (KR) 2008-71755

(51) Int. Cl. H01L 45/00

(52) U.S. Cl. 257/5; 257/2; 257/E45.002

(57) ABSTRACT

Non-volatile memory devices include an array of phase-changeable memory cells, which have first phase-changeable material patterns therein, and at least one phase-changeable fuse element. This phase-changeable fuse element includes a second phase-changeable material pattern therein with a higher crystallization temperature relative to the first phase-changeable material patterns in the array of phase-changeable memory cells. This higher crystallization temperature may be greater than about 300° C. According to additional embodiments of the present invention, the at least one phase-changeable fuse element includes a composite of the second phase-changeable material pattern and a third phase-changeable material pattern, which is formed of the same material at the first phase-changeable material patterns.

### REFERENCE TO PRIORITY APPLICATION

This U.S. non-provisional patent application claims priority to Korean Patent Application No. 10-2008-0071755, filed Jul. 23, 2008, the contents of which are hereby incorporated herein by reference.

### FIELD OF THE INVENTION

The present invention relates to integrated circuit devices and, more particularly, to non-volatile memory devices and methods of forming same.

### BACKGROUND

With the advance in electronic industries such as mobile communications and computers, there is a demand for semiconductor devices having characteristics such as fast read/write operations, nonvolatility, and a low operation voltage. However, currently used memory devices such as SRAM devices, DRAM devices, and flash memory devices cannot meet all the characteristics. Since a unit cell of a DRAM device includes one capacitor and one transistor configured to control the capacitor, the DRAM device has a larger unit cell area than a NAND flash memory device. A DRAM device is a volatile memory device requiring a refresh operation because data is stored in a capacitor of the DRAM device. An SRAM device is another volatile memory device having a high operation speed. A unit cell of an SRAM device typically includes six transistors. Therefore, the SRAM device suffers from the disadvantage that the unit cell occupies a considerably large area. Among current memory devices, flash memory devices (especially, NAND flash memory devices) can provide the highest integration density while being nonvolatile memory devices. Nonetheless, it is well known that these flash memory devices have the drawback of low operation speed.

In this regard, recent studies have focused on memory devices which can execute read/write operations at high speed, have nonvolatile characteristics, need not execute a refresh operation, and have a low operation voltage. Phase change random access memory (PRAM) devices are attractive candidates as nonvolatile memory devices which are capable of meeting the above technical demands. Since PRAM devices can update information approximately 10¹³ times or more, they have a long life and are able to execute a high-speed operation of approximately 30 nanoseconds.

A phase change pattern of a PRAM device can exhibit at least two distinguishable states, i.e., a crystalline state and an amorphous state and at least one intermediate state therebetween. Thus, the phase change pattern can be used as a memory element. The amorphous state has a higher resistivity than the crystalline state, and the intermediate state has a resistivity between those of the amorphous and crystalline states.

### SUMMARY

Non-volatile memory devices according to some embodiments of the present invention include an array of phase-changeable memory cells, which have first phase-changeable material patterns therein, and at least one phase-changeable fuse element. This phase-changeable fuse element includes a second phase-changeable material pattern therein with a higher crystallization temperature relative to the first phase-changeable material patterns in the array of phase-changeable memory cells. This higher crystallization temperature may be greater than about 300° C. According to additional embodiments of the present invention, the at least one phase-changeable fuse element includes a composite of the second phase-changeable material pattern and a third phase-changeable material pattern, which is formed of the same material at the first phase-changeable material patterns. In this composite, the second phase-changeable material pattern is in contact with the third phase-changeable material pattern. In particular, the second phase-changeable material pattern may have a U-shaped cross-section with a recess therein and this recess may be filled with the third phase-changeable material pattern.

Additional embodiments of the invention include an integrated circuit device having a fuse element therein. This fuse element may be formed as a phase-changeable fuse element containing at least two different phase-changeable materials having unequal crystallization temperatures. In particular, the fuse element may be formed so that a first one of the at least two different phase-changeable materials has a recess therein that is at least partially filed by a second one of the at least two different phase-changeable materials having a lower crystallization temperature relative to the first one of the at least two different phase-changeable materials. The integrated circuit device may also include an array of phase-changeable memory cells that are devoid of one of the at least two different phase-changeable memory cells having a higher crystallization temperature.

### BRIEF DESCRIPTION OF THE DRAWINGS

FIGS. 1 through 5 are cross-sectional views of memory devices according to embodiments of the present invention, respectively.

FIGS. 6A through 6D are cross-sectional views illustrating a method of forming a memory device according to an embodiment of the present invention.

FIGS. 7A through 7F are cross-sectional views illustrating a method of forming a memory device according to another embodiment of the present invention.

FIGS. 8A through 8E are cross-sectional views illustrating a method of forming a memory device according to yet another embodiment of the present invention.

FIGS. 9A through 9E are cross-sectional views illustrating a method of forming a memory device according to further another embodiment of the present invention.

FIGS. 10A and 10B are cross-sectional views illustrating a method of forming a memory device according to still another embodiment of the present invention.

### DETAILED DESCRIPTION OF THE EMBODIMENTS

PRAM devices may employ chalcogenide-based materials. As integration density of PRAM devices continues to increase, an error occurrence frequency may increase. The PRAM devices may adopt a redundancy structure to overcome yield reduction resulting from the error occurrence. Conventionally, a fuse element may be used in adopting the redundancy structure. The fuse element may be formed by a physical cutting process using laser or an electrical cutting process using current. In the physical cutting process, an area of a fuse box and processing steps may increase with increase of integration density. Fuse phase change elements according to embodiments of the present invention may be used in a fuse element. The fuse phase change elements may be programmed and repeatedly repaired even if error occurs after being packaged. A PRAM package process may include an infrared reflow step, which may be conducted at a temperature ranging from 220 to 270 degrees centigrade. For this reason, phase change of the fuse phase change element must not occur during the infrared reflow step. A cell phase change element and the fuse phase change element may be different in temperature characteristic. A phase change pattern of the cell phase change element may be formed of germanium-antimony-tellurium (GeSbTe or GST). A phase change pattern of the fuse phase change element may be formed of indium-antimony-tellurium (InSbTe) which is higher than the GST.

The present invention will now be described more fully hereinafter with reference to the accompanying drawings, in which preferred embodiments of the invention are shown. This invention, however, may be embodied in many different forms and should not be construed as limited to the embodiments set forth herein. Rather, these embodiments are provided so that this disclosure will be thorough and complete, and will fully convey the scope of the invention to those skilled in the art. In the drawings, the thicknesses of layers and regions are exaggerated for clarity. It will also be understood that when a layer is referred to as being “on” another layer or substrate, it can be directly on the other layer or substrate, or intervening layers may also be present. Like numbers refer to like elements throughout.

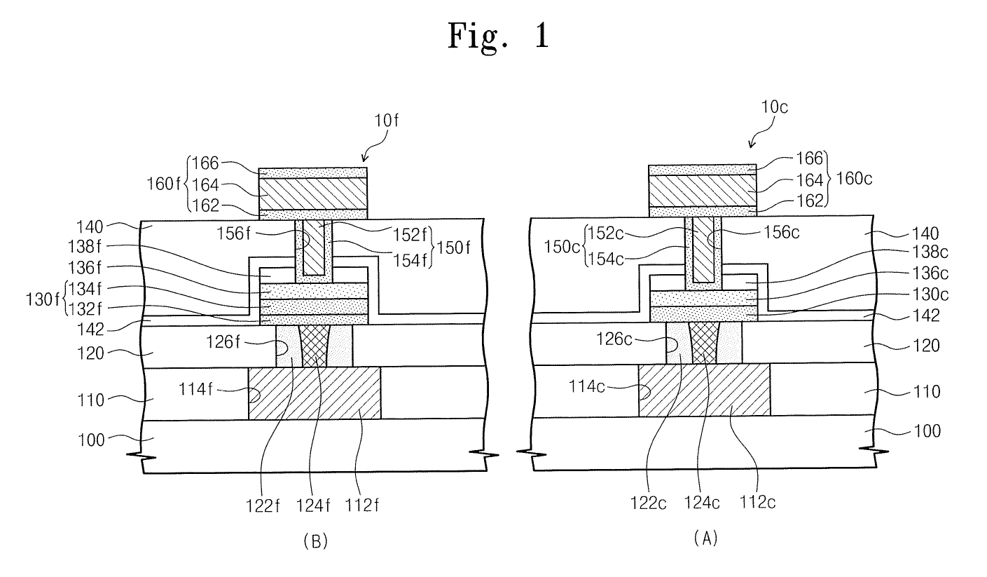

FIG. 1 is a cross-sectional view of an electric device according to an embodiment of the present invention.

Referring to FIG. 1, a substrate 100 may include a cell region A and a fuse region B. A fuse phase change element 10f may be disposed at the fuse region B, and a cell phase change element 10c may be disposed at the cell region A. The fuse phase change element 10f may include a fuse bottom interconnection 112f disposed at the fuse region B, a fuse phase change pattern 130f disposed on the fuse bottom interconnection 112f, and a fuse top interconnection 160f disposed on the fuse phase change pattern 130f. The cell phase change element 10c may include a cell bottom interconnection 112c disposed at the cell region A, a cell phase change pattern 130c disposed on the cell bottom interconnection 112c, and a cell top interconnection 160c disposed on the cell phase change pattern 130c. A crystallization temperature of the fuse phase change pattern 130f may be higher than that of the cell phase change patter 130c.

The substrate 100 may be a semiconductor substrate or a dielectric substrate and include at least one selected from the group consisting of a silicon substrate, a germanium substrate, and a silicon-on-insulator (SOI) substrate. The substrate 100 may include a cell region A and a fuse region B. The substrate 100 may include a bottom structure (not shown), which may include a diode or a transistor. A bottom interlayer dielectric 110 may be disposed on the substrate 100 and made of silicon oxide. Bottom interconnections 112c and 112f may be disposed in bottom contact holes 114c and 114f penetrating the bottom interlayer dielectric 110, respectively. The bottom interconnections 112c and 112f may include a conductive pad. The bottom interconnections 112c and 112f may include at least one selected from the group consisting of metal, metal compound, and doped semiconductor. The bottom interconnections 112c and 112f may include a cell bottom interconnection 112c disposed at the cell region A and a fuse bottom interconnection 112f disposed at the fuse region B, respectively. The bottom interconnections 112c and 112f may be electrically connected to the bottom structure. Top surfaces of the bottom interconnections 112c and 112f may have the same height as a top surface of the bottom interlayer dielectric 110.

An intermediate interlayer dielectric 120 may be disposed on the bottom interconnections 112c and 112f and/or the bottom interlayer dielectric 110. Intermediate contact holes 126c and 126f may be disposed through the intermediate interlayer dielectric 120 to expose the bottom interconnections 112c and 112f, respectively. The intermediate contact holes 126c and 126f may include a cell intermediate contact hole 126c formed at the cell region A and a fuse intermediate contact hole 126f formed at the fuse region. The intermediate dielectric 120 may be made of silicon oxide.

Bottom electrode spacers 122c and 122f may be disposed on sidewalls of the intermediate contact holes 126c and 126f, respectively. The bottom electrode spacers 122c and 122f may include silicon nitride or silicon oxynitride. The bottom electrode spacers 122c and 122f may include a cell bottom electrode spacer 122c disposed at the cell region A and a fuse bottom electrode spacer 122f disposed at the fuse region B. A thermal conductivity of the bottom electrode spacers 122c and 122f may be lower than that of the intermediate interlayer dielectric 120.

Bottom electrodes 124c and 124f may be disposed in the intermediate contact holes 126c and 126f, respectively. The bottom electrodes 124c and 124f may be provided to heat the phase change patterns 130c and 130f, respectively. The bottom electrodes 124c and 124f may include a cell bottom electrode 124c disposed at the cell region A and a fuse bottom electrode 124f disposed at the fuse region B. The bottom electrodes 124c and 124f may include at least one selected from the group consisting of metal nitride, metal, metal oxynitride, silicide, and conductive carbon. Specifically, the bottom electrodes 124c and 124f may include at least one selected from the group consisting of Ti, Ta, Mo, W, TiN, TaN, WN, MoN, NbN, TiSiN, TiAlN, TiBN, ZrSiN, WSiN, WBN, ZrAlN, MoSiN, TaSiN, TaAlN, TiW, TiSi, TaSi, TiON, TiAlON, WON, and TaON. A sectional area of the respective bottom electrodes 124c and 124f may be smaller than that of the respective phase change patterns 130c and 130f. If the bottom electrodes 124c and 124f decrease in size, a contact area may be reduced to increase contact resistance. Therefore, in case the contact resistance is high, the bottom electrodes 124c and 124f may rise to a high temperature even with a low current. The cell bottom interconnection 112c may be electrically connected to the cell bottom electrode 124c, and the fuse bottom interconnection 112f may be electrically connected to the cell bottom electrode 124f.

The phase change patterns 130c and 130f may be disposed on the bottom electrodes 124c and 124f, respectively. The phase change patterns 130c and 130f may include a cell phase change pattern 130c disposed at the cell region A and a fuse phase change pattern 130f disposed at the fuse region B. The phase change pattern 130c and 130f may extend in parallel with the top interconnections 160c and 160f.

In an alternative embodiment, the phase change patterns 130c and 130f may be island-shaped, contact plug-shaped or line-shaped patterns. The phase change patterns 130c and 130c may have various shapes.

The cell phase change pattern 130c of the cell region A may include at least one selected from the group consisting of Ge—Sb—Te, Sb—Te, As—Sb—Te, and Sb—Se. Specifically, the cell phase change pattern 130c may be made of Ge₂Sb²Te₅. The cell phase change pattern 130c may include one selected from the group consisting of As—Sb—Te-metal compound, As—Ge—Sb—Te-metal compound, metal-Sb—Te-metal compound, 5A group element-Sb—Te-metal compound, 6A group element-Sb—Te-metal compound, 5A group element-Sb—Se-metal compound, and 6A group element-Sb—Se-metal compound. There may be various ratios of the compounds. Specifically, the 5A group element may be nitrogen (N) or phosphorous (P), and the 6A group element may be oxygen (O) or sulfur (S).

The fuse phase change pattern 130f of the fuse region B may include at least one selected from the group consisting of In—Sb—Te, 5A group element-In—Sb—Te compound, and 6A group element-In—Sb—Te compound. A crystallization temperature of the fuse phase change pattern 130f may be higher than that of the cell phase change pattern 130c. The fuse phase change pattern 130f may include a first fuse phase change pattern 132f and a second fuse phase change pattern 134f. A crystallization temperature of the first fuse phase change pattern 132f may be higher than that of the second fuse phase change pattern 134f. The crystallization temperature of the first fuse phase change pattern 132f may be at least 300 degrees centigrade. The fuse phase change pattern 130f may use a material of a high crystallization temperature, and the cell phase change pattern 130c may use a material having excellent characteristics as a memory device. The second fuse phase change pattern 134f may be made of the same material as the cell phase change pattern 130c. Side surfaces of the first and second fuse phase change patterns 132f and 134f may be aligned to each other. The first fuse phase change pattern 132f may be heated by the fuse bottom electrode 124f to result in phase change thereof. A resistance state of the first fuse phase change pattern 132f may be unchanged due to an infrared reflow process. The fuse phase change element may be used as a one-time program cell.

Top electrodes 136c and 136f may be disposed on the cell phase change pattern 130c and the fuse phase change pattern 130f, respectively. The top electrodes 136c and 136f may include a cell top electrode 136c disposed at the cell region A and a fuse top electrode 136f disposed t the fuse region B. The top electrode 136c and 136f may include at least one selected from the group consisting of metal, metal nitride, and metal oxynitride. Specifically, the top electrodes 136c and 136f may include at least one selected from the group consisting of Ti, Ta, Mo, W, TiN, TaN, WN, MoN, NbN, TiSiN, TiAlN, TiBN, ZrSiN, WSiN, WBN, ZrAlN, MoSiN, TaSiN, TaAlN, TiW, TiSi, TaSi, TiON, TiAlON, WON, and TaON. Side surfaces of the top electrodes 136c and 136f may be aligned to those of the phase change patterns 130c and 130f.

Hard mask patterns 138c and 138f may be formed on the top electrodes 136c and 136f, respectively. The hard mask patterns 138c and 138f may include a cell hard mask pattern 138c formed at the cell region A and a fuse hard mask pattern 138f formed at the fuse region B. The hard mask patterns 138c and 138f may include one or both of silicon nitride and silicon oxynitride. Side surfaces of the cell phase change pattern 130c, the cell top electrode 136c, and the cell hard mask pattern 138c may be aligned to one another. Side surfaces of the fuse phase change pattern 130f, the fuse top electrode 136f, and the fuse hard mask pattern 138f may be aligned to one another. The hard mask patterns 138c and the 138f may be used as an etch stopper. The hard mask patterns 138c and 138f may act as at least one selected from the group consisting of a diffusion barrier layer, an oxidation barrier layer, and a heat transfer barrier layer.

A protection layer 142 may be disposed to conformally cover the top surfaces of the hard mask patterns 138c and 138f, the top electrodes 136c and 136f, the phase change patterns 130c and 130f, the side surfaces of the top electrodes 136c and 136f, and the top surface of the intermediate interlayer dielectric 120. The protection layer 142 may prevent the material of the phase change patterns 130c and 130f from diffusing out or reacting to another material. The protection layer 142 may be made of silicon nitride.

A top interlayer dielectric 140 may be disposed on the protection layer 142. The top interlayer dielectric 140 may be made of silicon oxide. A top surface of the top interlayer dielectric 140 may be higher than that of the hard mask patterns 138c and 138f. The top surface of the top interlayer dielectric 140 may be planarized. Top contact holes 156c and 156f may be formed through the top interlayer dielectric 140, the protection layer 142, and the hard mask patterns 138c and 138f to expose the top electrodes 136c and 136f. The top contact holes 156c and 156f may include a cell top contact hole 156c formed at the cell region A and a fuse top contact hole 156f formed at the fuse region B. Top contact plugs 150c and 150f may be disposed in the top contact holes 156c and 156f, respectively. The top contact plug 150c and 150f may include a cell top contact plug 150c filling the cell top contact hole 156c and a fuse top contact plug 150f filling the fuse top contact hole 156f. The top contact plugs 150c and 150f may be made of a conductive material. The top contact plugs 150c and 150f may include, for example, tungsten (W). The top contact plug 150c may have a multi-layer structure including a barrier material 152c and a conductive material 154c which are sequentially stacked, and the top contact plug 150f may have a multi-layer structure including a barrier material 152f and a conductive material 154f which are sequentially stacked.

Top interconnections 160c and 160f may be disposed on the top interlayer dielectric 140. The top interconnections 160c and 160f may be electrically connected to the top contact plugs 150c and 150f, respectively. The top interconnections 160c and 160f may include at least one selected from the group consisting of metal, metal compound, and doped semiconductor. The top interconnections 160c and 160f may have a multi-layer structure including a barrier layer 162, a conductive layer 164, and a barrier layer 166 which are stacked in the order named. The top interconnections 160c and 160f may include a cell top interconnection 160c disposed at the cell region A and a fuse top interconnection 160f disposed at the fuse region B. The fuse top interconnection 160f may be electrically connected to a fuse controller (not shown).

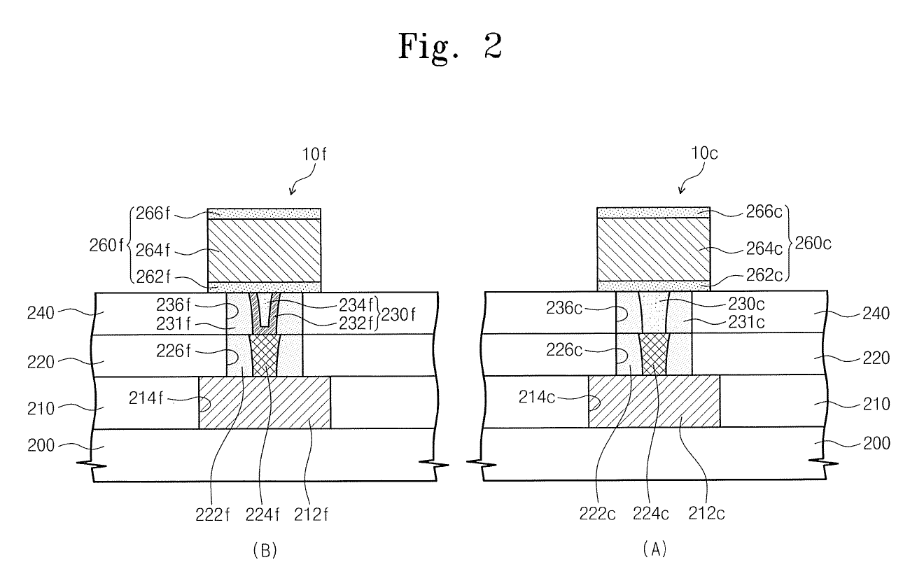

FIG. 2 is a cross-sectional view of an electric device according to another embodiment of the present invention.

Referring to FIG. 2, a substrate 200 may include a cell region A and a fuse region B. A fuse phase change element 10f may be disposed at the fuse region A, and a cell phase change element 10c may be disposed at the cell region A. The fuse phase change element 10f may include a fuse bottom interconnection 212f disposed at the fuse region A, a fuse phase change pattern 230f disposed on the fuse bottom interconnection 230f, and a fuse top interconnection 260f disposed on the fuse phase change pattern 230f. The cell phase change element 10c may include a cell bottom interconnection 212c disposed at the cell region A, a cell phase change pattern 230c disposed on the cell bottom interconnection 212c, and a cell top interconnection 260c disposed on the cell phase change pattern 230c. A crystallization temperature of the fuse phase change pattern 230f may be higher than that of the cell phase change pattern 230c. A cell bottom electrode 224c may be disposed between the cell phase change pattern 230c and the cell bottom interconnection 214c, and a fuse bottom electrode 224f may be disposed between the fuse phase change pattern 230f and the fuse bottom interconnection 214f.

The substrate 200 may a semiconductor substrate or a dielectric substrate and may include at least one selected from the group consisting of a silicon substrate, a germanium substrate, and a silicon-on-insulator (SOI) substrate. The substrate 100 may include a cell region A and a fuse region B. The substrate 100 may include a bottom structure (not shown), which may include a diode or a transistor.

A bottom interlayer dielectric 210 may be disposed on the substrate 200. The bottom interlayer dielectric 210 may be made of silicon oxide. A top surface of the bottom interlayer dielectric 210 may be planarized. Bottom interconnections 212c and 212f may be disposed in bottom contact holes 214c and 214f penetrating the bottom interlayer dielectric 210, respectively. The bottom interconnections 212c and 212f may include a conductive pad. The bottom interconnections 212c and 212f may include at least one selected from the group consisting of metal, metal compound, and doped semiconductor. The bottom interconnections 212c and 212f may include a cell bottom interconnection 212c disposed at the cell region A and a fuse bottom interconnection 212f disposed at the fuse region B. The top surface of the bottom interlayer dielectric 210 may have the same height as that of the bottom interconnections 212c and 212f.

An intermediate interlayer dielectric 220 may be disposed on the bottom interconnections 212c and 212f and/or the bottom interlayer dielectric 210. The intermediate interlayer dielectric 220 may be made of silicon oxide. Intermediate contact holes 226c and 226f may be disposed trough the intermediate interlayer dielectric 220 to expose the bottom interconnections 212c and 212f. The intermediate contact holes 226c and 226f may include a cell intermediate contact hole 226c formed at the cell region A and a fuse intermediate contact hole 226f formed at the fuse region B. The intermediate interlayer dielectric 220 may be made of silicon oxide. Bottom electrode spacers 222c and 222c may be disposed on sidewalls of the intermediate contact holes 226c and 226f, respectively. The bottom electrode spacer 222c and 222f may include silicon nitride or silicon oxynitride. The bottom electrode spacers 222c and 222f may include a cell bottom electrode spacer 222c disposed at the cell region A and a fuse bottom electrode spacer 222f disposed at the fuse region B. Bottom electrodes 224c and 224f may be disposed in the intermediate contact holes 226c and 226f, respectively. The bottom electrodes 224c and 224f may be provided to heat the phase change patterns 230c and 230f, respectively. The bottom electrodes 224c and 224f may include a cell bottom electrode 224c disposed at the cell region A and a fuse bottom electrode 224f disposed at the fuse region B. Top surfaces of the bottom electrodes 224c and 224f may have same height as a top surface of the intermediate interlayer dielectric 220. The bottom electrodes 224c and 224f may include at least one selected from the group consisting of metal nitride, metal, metal oxynitride, silicide, and conductive carbon. Specifically, the bottom electrodes 224c and 224f may include at least one selected from the group consisting of Ti, Ta, Mo, W, TiN, TaN, WN, MoN, NbN, TiSiN, TiAlN, TiBN, ZrSiN, WSiN, WBN, ZrAlN, MoSiN, TaSiN, TaAlN, TiW, TiSi, TaSi, TiON, TiAlON, WON, and TaON. A sectional area of the respective bottom electrodes 124c and 124f may be smaller than that of the respective phase change patterns 130c and 130f. A thermal conductivity of the bottom electrode spacers 222c and 222f may be lower than that of the intermediate interlayer dielectric 220.

A top interlayer dielectric 240 may be disposed on the intermediate interlayer dielectric 220 and made of silicon oxide. Phase change contact holes 236c and 236f may be formed through the top interlayer dielectric 240 to expose the bottom electrodes 224c and 224f, respectively. The phase change contact holes 236c and 236f may include a cell phase change contact hole 236c formed at the cell region A and a fuse phase change contact hole 236f formed at the fuse region B. Phase change spacers 231c and 231f may be formed on sidewalls of the phase change contact holes 236c and 236f, respectively. The phase change spacers 231c and 231f may include a silicon nitride layer or a silicon oxynitride layer. A thermal conductivity of the phase change spacers 231c and 231f may be lower than that of the top interlayer dielectric 240. The phase change spacers 231c and 231f may act as a diffusion barrier layer. The phase change spacers 231c and 231f may include a cell phase change spacer 231c disposed at the cell region A and a fuse phase change spacer 231f disposed at the fuse region B. The phase change patterns 230c and 230f may be disposed in the phase change contact holes 236c and 236f, respectively. The phase change patterns 230c and 230f may include a cell phase change pattern 230c disposed at the cell region A and a fuse phase change pattern 230f disposed at the fuse region B.

According to an alternative embodiment, the phase change patterns 230c and 230f are not limited to contact plug-shaped patterns. The phase change patterns 230c and 230f may have a line shape. The phase change patterns 230c and 230f may extend in parallel with the top interconnections 260c and 260c.

The cell phase change pattern 230c of the cell region A may include at least one selected from the group consisting of Ge—Sb—Te, Sb—Te, As—Sb—Te, and Sb—Se. Specifically, the cell phase change pattern 230c may be made of Ge₂Sb₂Te₅. The cell phase change pattern 130c may include one selected from the group consisting of As—Sb—Te-metal compound, As—Ge—Sb—Te-metal compound, metal-Sb—Te-metal compound, 5A group element-Sb—Te-metal compound, 6A group element-Sb—Te-metal compound, 5A group element-Sb—Se-metal compound, and 6A group element-Sb—Se-metal compound. There may be various ratios of the compounds. Specifically, the 5A group element may be nitrogen (N) or phosphorous (P), and the 6A group element may be oxygen (O) or sulfur (S). The cell phase change pattern 230c may have the shape of inverse truncated cone.

The fuse phase change pattern 230f may include a first fuse phase change pattern 232f and a second fuse phase change pattern 234f. A crystallization temperature of the first fuse phase change pattern 232f may be higher than that of the second fuse phase change pattern 234f. The crystallization temperature of the first fuse phase change pattern 232f may be at least 300 degrees centigrade. The fuse phase change pattern 130f may use a material of a high crystallization temperature, and the cell phase change pattern 130c may use a material having excellent characteristics as a memory device. The first fuse phase change pattern 232f may be a pot-shaped pattern and be in contact with a side surface of the fuse phase change pattern 232f. A bottom surface of the first fuse phase change pattern 232f may be in contact with a top surface of the fuse bottom electrode 224f. The second fuse phase change pattern 234f may be disposed to fill the inside of the first fuse phase change pattern 232f and have the shape of inverse truncated cone. The top surface of the first fuse phase change pattern 232f may have the same height as that of the second fuse phase change pattern 234f.

The first fuse phase change pattern 232f may include at least one selected from the group consisting of In—Sb—Te, 5A group element-In—Sb—Te compound, and 6A group element-In—Sb—Te compound. A crystallization temperature of the first fuse phase change pattern 232f may be higher than that of the cell phase change pattern 230c. The second fuse phase change pattern 234f may be made of the same material as the cell phase change pattern 230c. Current flowing to the fuse bottom electrode 224f may result in phase change of the first fuse phase change pattern 232f. A resistance state of the first fuse phase change pattern 232f may be unchanged due to an infrared reflow process. The fuse phase change element may be used as a one-time program cell.

Top interconnections 260c and 260f may be disposed on the phase change pattern 230c and 230f, respectively. The top interconnections 260c and 260f may include a cell top interconnection 260c disposed at the cell region A and a fuse top interconnection 260f disposed at the fuse region B. The top interconnections 260c and 260f may be electrically connected to the phase change patterns 230c and 230f, respectively. The top interconnections 260c and 260f may include at least one selected from the group consisting of metal, metal compound, and doped semiconductor. The cell top interconnection 260c may have a multi-layer structure including a diffusion barrier layer 262c, a metal layer 264c, and a diffusion barrier layer 266c which are sequentially stacked, and the fuse top interconnection 260f may have a multi-layer structure including a diffusion barrier layer 262f, a metal layer 264f, and a diffusion barrier layer 266f which are sequentially stacked.

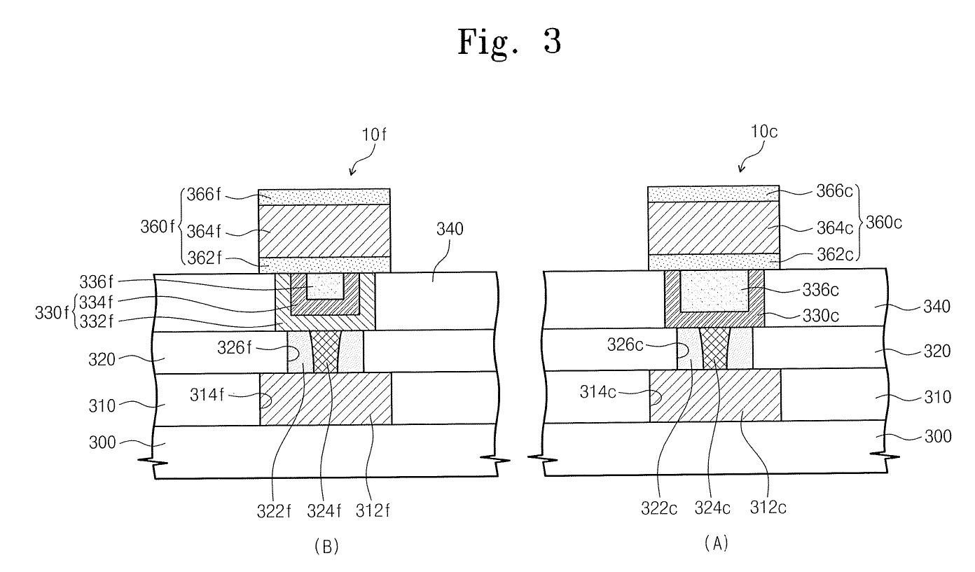

FIG. 3 is a cross-sectional view of an electric device according to yet another embodiment of the present invention.

Referring to FIG. 3, the electric device has a similar structure to the electric device described in FIG. 2. Thus, duplicate explanations thereof may be omitted. A substrate 300 may include a cell region A and a fuse region B. A fuse phase change element 10f may be disposed at the fuse region B, and a cell phase change element 10c may be disposed at the cell region A. The fuse phase change element 10f may include a fuse bottom interconnection 312f disposed at the fuse region B, a fuse phase change pattern 330f disposed on the fuse bottom interconnection 312f, and a fuse top interconnection 360f disposed on the fuse change pattern 330f. The cell phase change element 10c may include a cell bottom interconnection 312c disposed at the cell region A, a cell phase change pattern 330c disposed on the cell bottom interconnection 312c, and a cell top interconnection 360c disposed on the cell phase change pattern 330c. A crystallization temperature of the fuse phase change pattern 330f may be higher than that of the cell phase change pattern 330c.

A bottom interlayer dielectric 310 may be disposed on the substrate 300. The bottom interconnections 312c and 312f may be disposed in the bottom interlayer dielectric 310. An intermediate interlayer dielectric 320 may be disposed on the bottom interlayer dielectric 310. Bottom electrodes 324c and 324f may be disposed in the intermediate interlayer dielectric 320. The bottom electrodes 324c and 324f may be electrically connected to the bottom interconnections 312c and 312f, respectively. The bottom electrodes 324c and 324f may include a cell bottom electrode 324c disposed at the cell region A and a fuse bottom electrode 324f disposed at the fuse region B. Bottom electrode spacers 322c and 322f may be disposed between the cell bottom electrode 324c and the intermediate interlayer dielectric 320 and between the fuse bottom electrode 324f and the intermediate interlayer dielectric 320, respectively. The bottom electrode spacers 322c and 322f may include a cell bottom electrode spacer 322c disposed at the cell region A and a fuse bottom electrode spacer 322f disposed at the fuse region B.

A top interlayer dielectric 340 may be disposed on the intermediate interlayer dielectric 320. Phase change patterns 330c and 330f may be disposed in the top interlayer dielectric 340. The phase change patterns 330c and 330f may include a cell phase change pattern 330c disposed at the cell region A and a fuse phase change pattern 330f disposed at the fuse region B.

The cell phase change pattern 330c may be a pot-shaped pattern. The inside of the cell phase change pattern 330 may be filled with a cell top electrode 336c. A height of the cell phase change pattern 330c may have the same height as that of the cell top electrode 336c.

The fuse phase change pattern 330f may include a first fuse phase change pattern 332f and a second fuse phase pattern 334f. The pot-shaped second phase change pattern 332f may be disposed in the pot-shaped first fuse phase change pattern 332f. A fuse top electrode 336f may be disposed in the pot-shaped second fuse phase change pattern 334f. A top surface of the fuse phase change pattern 330f may have same height as that of the fuse top electrode 336f. A crystallization temperature of the first fuse phase change pattern 332f may be higher than that of the second fuse phase change pattern 334f. The second fuse phase change pattern 334f may be made of the same material as the cell phase change pattern 330c.

According to an alternative embodiment, the phase change patterns 330c and 330f may extend in a direction of the top interconnections 360c and 360f. There may be various shapes of the phase change patterns 330c and 330f.

The top interconnections 360c and 360f may be disposed on the top electrodes 336c and 336f and the phase change patterns 330c and 330f. The top interconnections 360c and 360f may include a cell top interconnection 360c disposed at the cell region A and a fuse top interconnection 360f disposed at the fuse region B. The cell top interconnection 360c may have a multi-layer structure including a diffusion barrier layer 362c, a metal layer 364c, and a diffusion barrier layer 366c which are sequentially stacked, and the fuse top interconnection 360f may have a multi-layer structure including a diffusion barrier layer 362f, a metal layer 364f, and a diffusion barrier layer 366f which are sequentially stacked.

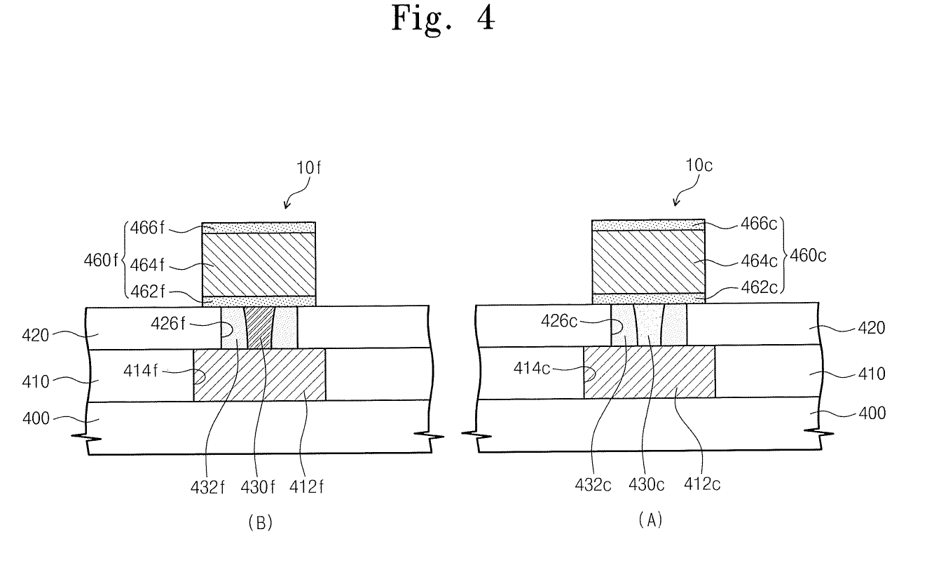

FIG. 4 is a cross-sectional view of an electric device according to further another embodiment of the present invention.

Referring to FIG. 4, the electric device has a similar structure to the electric device described in FIG. 3. Thus, duplicate explanations thereof may be omitted. A substrate 400 may include a cell region A and a fuse region B. A fuse phase change element 10f may be disposed at the fuse region B, and a cell phase change element 10c may be disposed at the cell region A. The fuse phase change element 10f may include a fuse bottom interconnection 412f disposed at the fuse region B, a fuse phase change pattern 432f disposed on the fuse bottom interconnection 412f, and a fuse top interconnection 460f disposed on the fuse phase change pattern 432f. The cell phase change element 10c may include a cell bottom interconnection 412c disposed at the cell region A, a cell phase change pattern 434c disposed on the cell bottom interconnection 412c, and a cell top interconnection 460c disposed on the cell phase change pattern 434c. A crystallization temperature of the fuse phase change pattern 432f may be higher than that of the cell phase change pattern 434c.

A bottom interlayer dielectric 410 may be disposed on the substrate 400. The bottom interconnections 412c and 412f may be disposed in the bottom interlayer dielectric 410. An intermediate interlayer dielectric 420 may be disposed on the bottom interlayer dielectric 410.

Phase change patterns 430c and 430f may be disposed in the intermediate interlayer dielectric 430. A cell phase change spacer 432c may be disposed on a sidewall of the cell phase change pattern 430c, and a fuse phase change spacer 432f may be disposed on a sidewall of the fuse phase change pattern 430f. Phase change of the phase change patterns 430c and 430f may be made not by heat transferred to the phase change patterns 430c and 430f from a separate heater but by current flowing to the phase change patterns 430c and 430f. The cell phase change pattern 430c may include at least one selected from the group consisting of Ge—Sb—Te, Sb—Te, As—Sb—Te, and Sb—Se. The fuse phase change pattern 430f may include one selected from the group consisting of In—Sb—Te, 5A group element-In—Sb—Te compound, and 6A group element-In—Sb—Te compound.

The top interconnections 460c and 460f may include a cell top interconnection 460c disposed at the cell region A and a fuse top interconnection 460f disposed at the fuse region B. The cell top interconnection 460c may have a multi-layer structure including a diffusion barrier layer 462c, a metal layer 464c, and a diffusion barrier layer 466c which are sequentially stacked, and the fuse top interconnection 460f may have a multi-layer structure including a diffusion barrier layer 462f, a metal layer 464f, and a diffusion barrier layer 466f which are sequentially stacked.

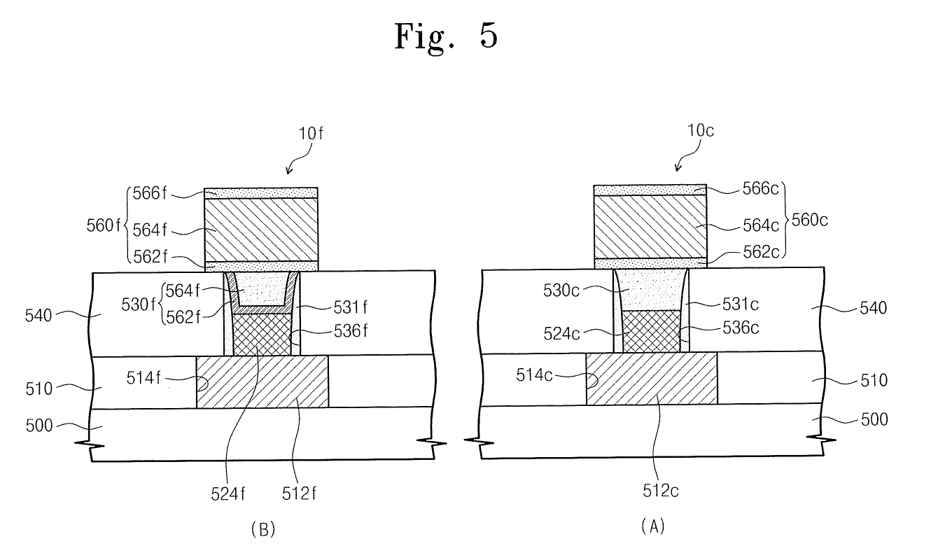

FIG. 5 is a cross-sectional view of an electric device according to further another embodiment of the present invention.

Referring to FIG. 5, the electric device has a similar structure to the electric device described in FIG. 2. A substrate 500 may include a cell region A and a fuse region B. A fuse phase change element 10f may be disposed at the fuse region B, and a cell phase change element 10c may be disposed at the cell region A. The fuse phase change element 10f may include a fuse bottom interconnection 512f disposed at the fuse region B, a fuse bottom electrode 524f disposed on the fuse bottom interconnection 512f, a fuse phase change pattern 530f disposed on the fuse bottom electrode 524f, and a fuse top interconnection 560f disposed on the fuse phase change pattern 530f. The cell phase change element 10c may include a cell bottom interconnection 512c disposed at the cell region A, a cell bottom electrode 524c disposed on the cell bottom interconnection 512c, a cell phase change pattern 530c disposed on the cell bottom electrode 524c, and a cell top interconnection 560c disposed on the cell phase change pattern 530f. A crystallization temperature of the fuse phase change pattern 530f may be higher than that of the cell phase change pattern 530c.

A bottom interlayer dielectric 510 may be disposed on the substrate 500. Bottom interconnections 512c and 512f may be disposed in the bottom interlayer dielectric 510. The bottom interconnections 512c and 512f may include a cell bottom interconnection 512c disposed at the cell region A and a fuse bottom interconnection 512f disposed at the fuse region B.

A top interlayer dielectric 540 may be disposed on the bottom interlayer dielectric 510.

Bottom electrodes 524c and 524f and the phase change patterns 530c and 530f may be sequentially stacked in the top interlayer dielectric 540. The bottom electrodes 524c and 524f may include a cell bottom electrode 524c disposed at the cell region A and a fuse bottom electrode 524f disposed at the fuse region B. The phase change patterns 530c and 530f may include a cell phase change pattern 530c disposed at the cell region A and a fuse phase change pattern 530f disposed at the fuse region B.

A cell phase change spacer 531c may be disposed on sidewalls of the cell phase change pattern 530c and the cell bottom electrode 524c, and a fuse phase change spacer 531f may be disposed on sidewalls of the phase change patterns 530f and the fuse bottom electrode 524c. Heat generated from the bottom electrode 524c and 524f is transferred to the phase change patterns 530c and 530f, leading to phase change of the phase change patterns 530c and 530f.

The top interconnections may include a cell top interconnection 560c disposed at the cell region A and a fuse top interconnection 560f disposed at the fuse region B. The cell top interconnection 560c may has a multi-layer structure including a diffusion barrier layer 562c, a metal layer 564c, and a diffusion barrier layer 566c which are sequentially stacked, and the fuse top interconnection 560f may have a multi-layer structure including a diffusion barrier layer 562f, a metal layer 564f, and a diffusion barrier layer 566f which are sequentially stacked.

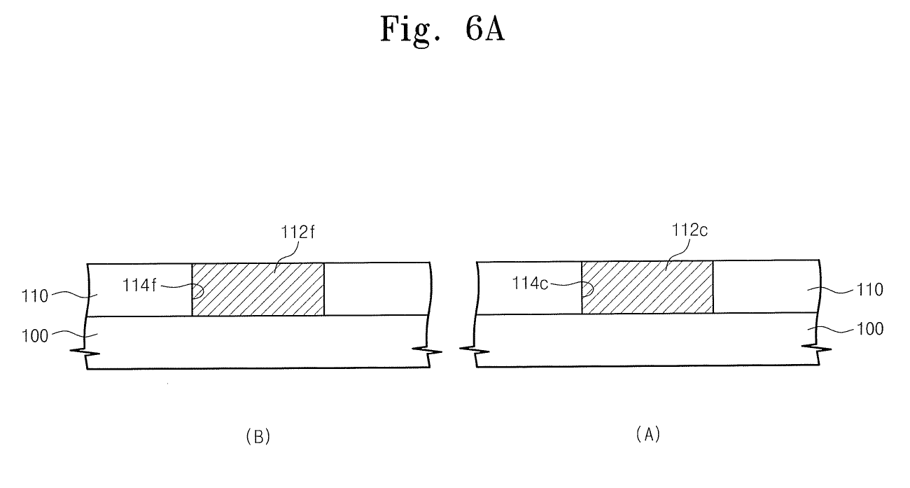

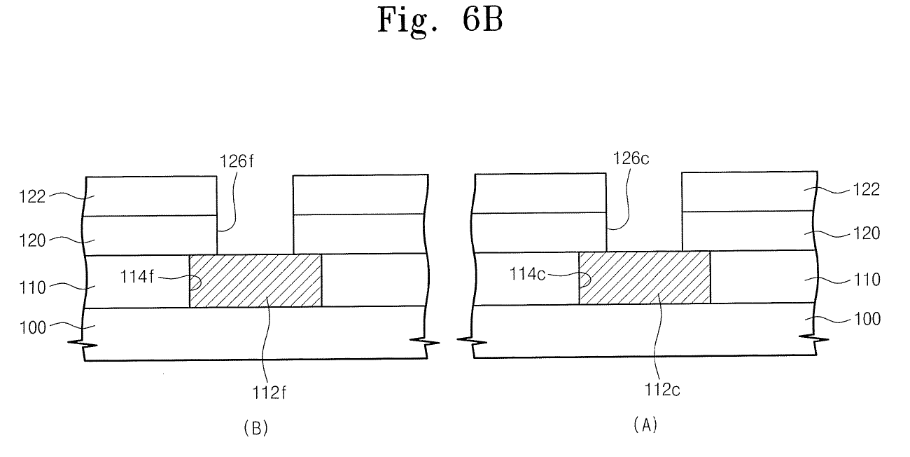

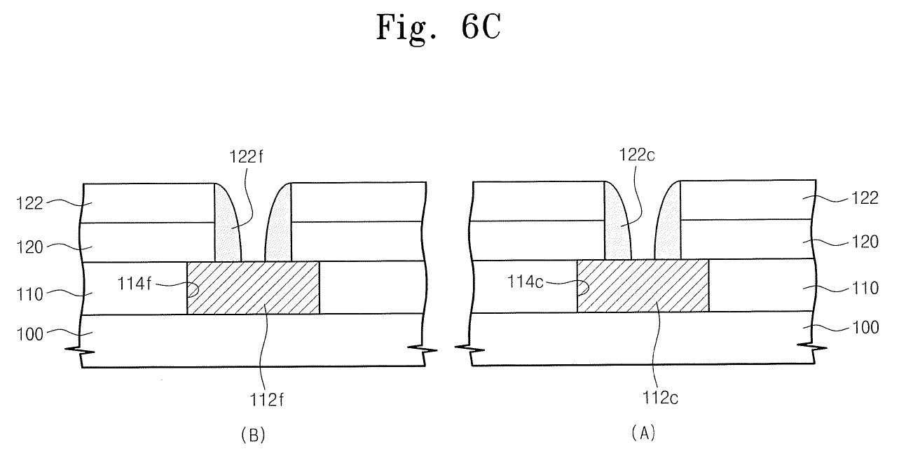

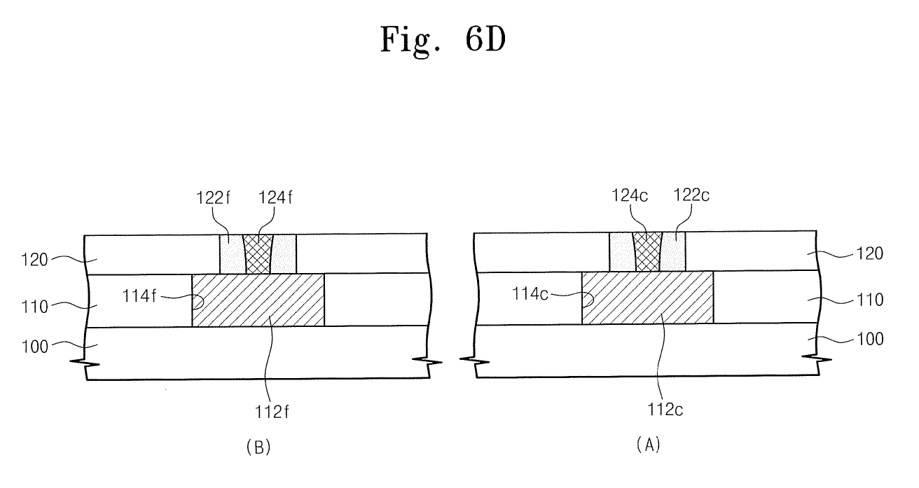

FIGS. 6A through 6D are cross-sectional views illustrating a method of forming an electric device according to an embodiment of the present invention.

Referring to FIG. 6A, a substrate 100 may include a fuse region A and a cell region B. A bottom interlayer dielectric 110 is formed on the substrate 100. The bottom interlayer dielectric 110 may be formed by means of chemical vapor deposition (CVD) or spin coating. The bottom interlayer dielectric 110 may be formed of silicon oxide. A top surface of the bottom interlayer dielectric 110 may be planarized. The bottom interlayer dielectric 110 may be patterned to form bottom contact holes 114c and 114f, which may include a cell bottom contact hole 114c formed at the cell region A and a fuse bottom contact hole 114f formed at the fuse region B. The cell contact hole 114c and the fuse contact hole 114f may be formed at the same time. A bottom interconnection layer (not shown) may be deposited to cover the bottom contact holes 114c and 114f and the bottom interlayer dielectric 110. The substrate 100 including the deposited bottom interconnection layer may be planarized to form bottom interconnections 112c and 112f, which may include a cell bottom interconnection 112c formed at the cell region A and a fuse bottom interconnection 112f formed at the fuse region B. The planarization of the substrate 100 including the deposited bottom interconnection layer may be done by means of a chemical mechanical polishing (CMP) process or an etch-back process.

Referring to FIG. 6B, a first intermediate interlayer dielectric 120 and a second intermediate interlayer dielectric 122 may be sequentially stacked on the bottom interconnections 114f and 114c and the bottom interlayer dielectric 110. The first intermediate interlayer dielectric 120 may be formed of silicon oxide, and the second intermediate interlayer dielectric 122 may be formed of silicon nitride or silicon oxynitride. By patterning the second and first intermediate interlayer dielectrics 122 and 120, intermediate contact holes 126c and 126f may be formed to expose the bottom interconnections 112c and 112f, respectively. The intermediate interlayer contact holes 126c and 126f may include a cell intermediate contact hole 126c formed at the cell region A and a fuse intermediate contact hole 126f formed at the fuse region B.

Referring to FIG. 6C, a bottom electrode spacer layer (not shown) may be conformally formed on the intermediate contact holes 126c and 126f and the second intermediate interlayer dielectric 122. The bottom electrode spacer layer may be formed of silicon nitride. The bottom electrode spacer layer may be anisotropically etched to form bottom electrode spacers 122c and 122f at sidewalls of the intermediate contact holes 126c and 126f. The bottom electrode spacers 122c and 122f may include a cell bottom electrode spacer 122c formed at the cell region A and a fuse bottom electrode spacer 122f formed at the fuse region B.

Referring to FIG. 6D, a bottom electrode layer (not shown) may be deposited to fill the intermediate contact holes 126c and 126f. The substrate 100 may be planarized down to a top surface of the first intermediate interlayer dielectric 120 to form bottom electrodes 124c and 124f, which may include a cell bottom electrode 124c formed at the cell region A and a fuse bottom electrode 124f formed at the fuse region B. Top surfaces of the bottom electrode spacers 122c and 122f may have same height as those of the bottom electrodes 124c and 124f.

Returning to FIG. 1, a first phase change layer (not shown) is deposited on the substrate 100. The first phase change layer at the cell region A is patterned to be removed. A second phase change layer (not shown), a top electrode layer (not shown), and a hard mask layer (not shown) may be sequentially stacked. The hard mask layer, the top electrode layer, and the second phase change layer at the cell region A may be successively patterned to form a cell hard mask pattern 138c, a cell top electrode 136c, and a cell phase change pattern 130c. The hard mask layer, the top electrode layer, and the second phase change layer at the fuse region B may be successively patterned to form a fuse hard mask pattern 138f, a fuse top electrode 136f, and a fuse phase change pattern 130f. The fuse phase change pattern 130f may include a first fuse phase change pattern 132f and a second fuse phase change pattern 134f.

A protection layer 142 may be conformally formed on the hard mask patterns 138c and 138f and the first intermediate interlayer dielectric 120. The protection layer 142 may be made of silicon nitride. A top interlayer dielectric 140 may be formed on the substrate 100 where the protection layer 142 is formed. A top surface of the top interlayer dielectric 140 may be planarized and may be higher than top surfaces of the hard mask patterns 138c and 138f. The top interlayer dielectric 140 may be patterned down to top surfaces of the top electrodes 136c and 136f to form top contact holes 156c and 156f, which may include a cell top contact hole 156c formed at the cell region A and a fuse top contact hole 156f formed at the fuse region B. A conductive layer (not shown) may be formed on the top contact holes 156c and 156f and the top interlayer dielectric 140. The conductive layer may be formed to fill the top contact holes 156c and 156f. The substrate 100 including the deposited conductive layer may be planarized to form top contact plugs 150c and 150f, which may include a cell top contact plug 150c formed at the cell region A and a fuse top contact hole 150f formed at the fuse region B. The cell top contact plug 150c may have a multi-layer structure including a diffusion barrier layer 154c and a conductive layer 152c which are sequentially stacked, and the fuse top contact plug 150f may have a multi-layer structure including a diffusion barrier layer 154f and a conductive layer 152f which are sequentially stacked.

A top interconnection layer (not shown) may be formed on the substrate 100 where the top contact plugs 150c and 150f are formed. The top interconnection layer may be patterned to form top interconnections 160c and 160f, which may include a cell top interconnection 160c formed at the cell region A and a fuse top interconnection 160f formed at the fuse region B. Each of the cell top interconnection 160c and the fuse top interconnection layer 160f may include a multi-layer structure including a diffusion barrier layer 162, an interconnection layer 164, and a diffusion barrier layer 166 which are sequentially stacked.

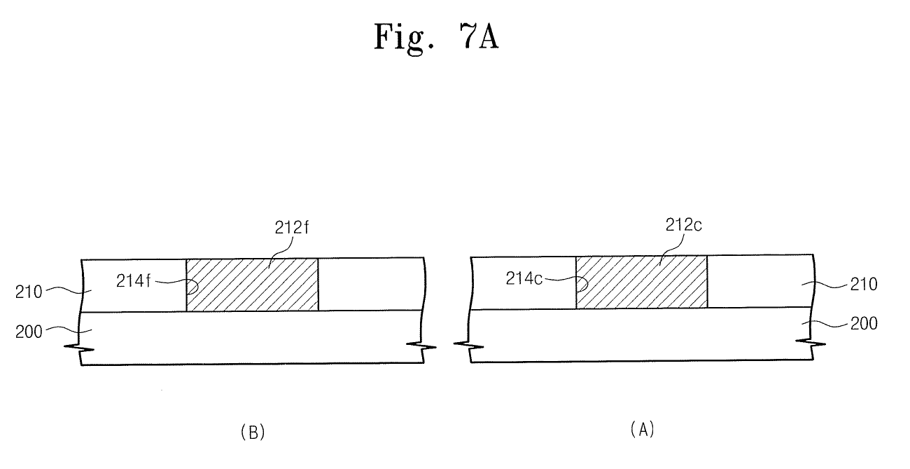

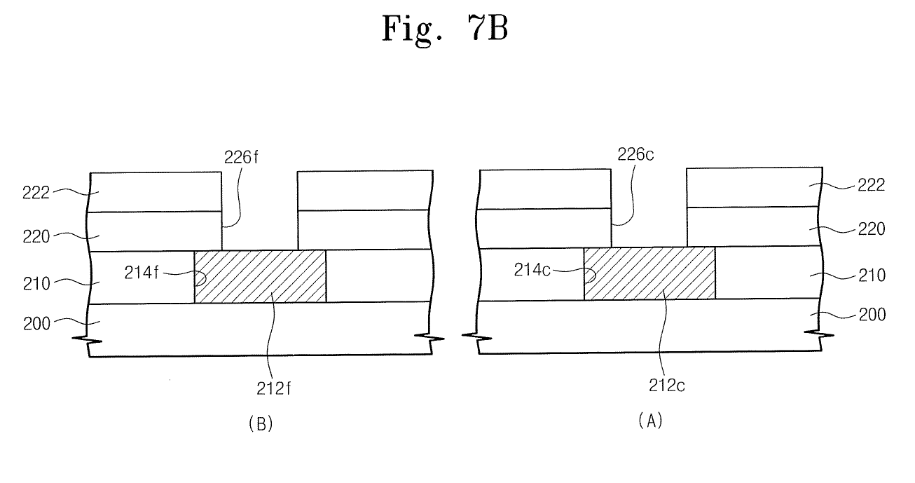

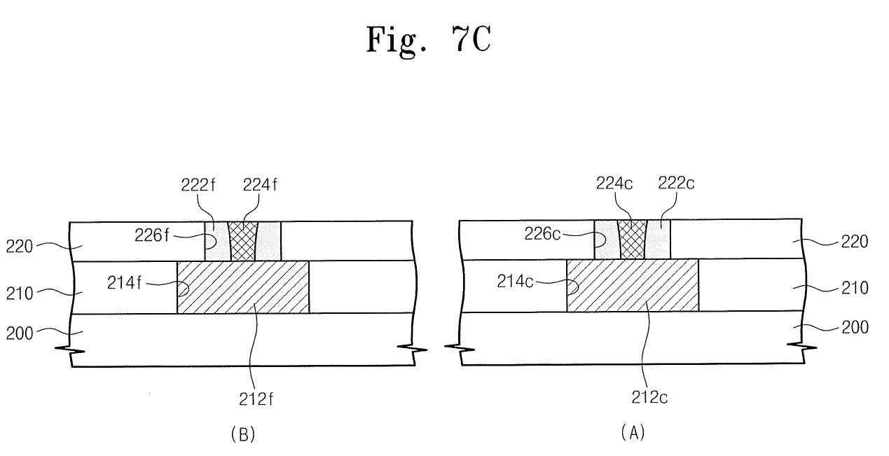

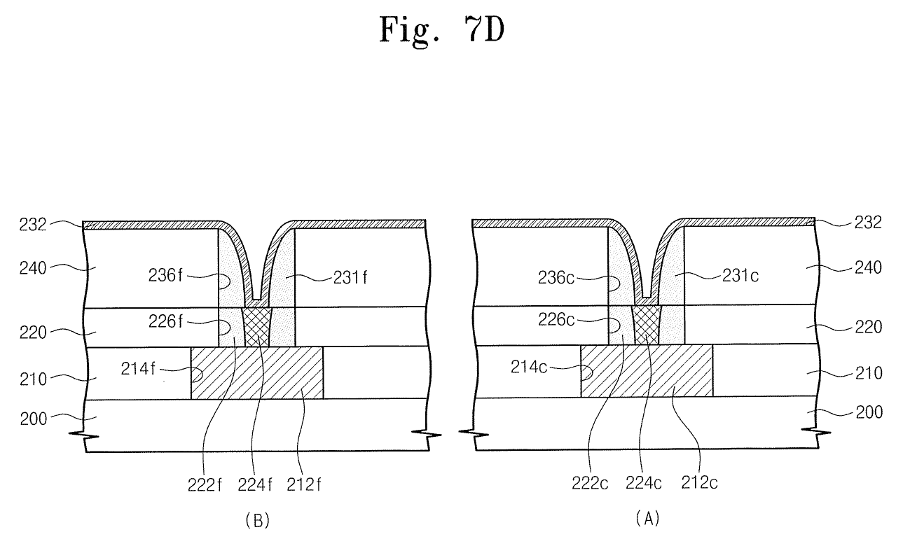

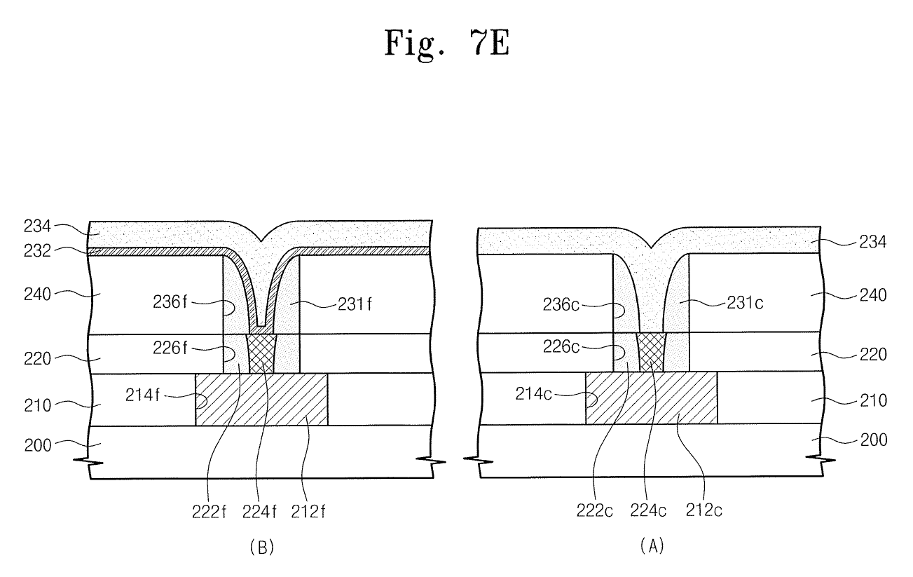

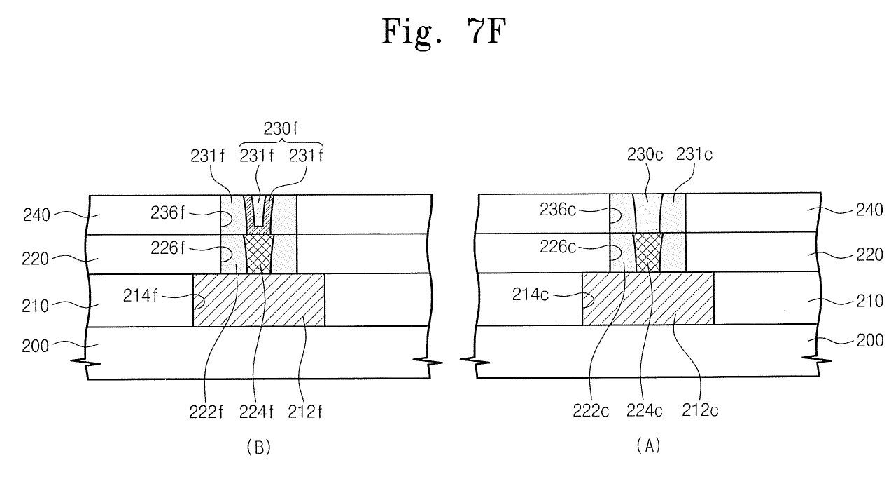

FIGS. 7A through 7F are cross-sectional views illustrating a method of forming an electric device according to another embodiment of the present invention.

Referring to FIG. 7A, a substrate 200 may include a fuse region A and a cell region B. A bottom interlayer dielectric 210 is formed on the substrate 200. The bottom interlayer dielectric 210 may be formed by means of chemical vapor deposition (CVD) or spin coating. The bottom interlayer dielectric 210 may be formed of silicon oxide. A top surface of the bottom interlayer dielectric 210 may be planarized. The bottom interlayer dielectric 210 may be patterned to form bottom contact holes 214c and 214f, which may include a cell bottom contact hole 214c formed at the cell region A and a fuse bottom contact hole 214f formed at the fuse region B. The cell contact hole 214c and the fuse contact hole 214f may be formed at the same time. A bottom interconnection layer (not shown) may be deposited to cover the bottom contact holes 214c and 214f and the bottom interlayer dielectric 210. The substrate 200 including the deposited bottom interconnection layer may be planarized to form bottom interconnections 212c and 212f, which may include a cell bottom interconnection 212c formed at the cell region A and a fuse bottom interconnection 212f formed at the fuse region B. The planarization of the substrate 200 including the deposited bottom interconnection layer may be done by means of a chemical mechanical polishing (CMP) process or an etch-back process.

Referring to FIG. 7B, a first intermediate interlayer dielectric 220 and a second intermediate interlayer dielectric 222 may be sequentially stacked on the bottom interconnections 214f and 214c and the bottom interlayer dielectric 210. The first intermediate interlayer dielectric 220 may be formed of silicon oxide, and the second intermediate interlayer dielectric 222 may be formed of silicon nitride or silicon oxynitride. By patterning the second and first intermediate interlayer dielectrics 222 and 220, intermediate contact holes 226c and 226f may be formed to expose the bottom interconnections 212c and 212f, respectively. The intermediate interlayer contact holes 226c and 226f may include a cell intermediate contact hole 226c formed at the cell region A and a fuse intermediate contact hole 226f formed at the fuse region B.

Referring to FIG. 7C, a bottom electrode spacer layer (not shown) may be conformally formed on the interlayer contact holes 226c and 226f and the second intermediate interlayer dielectric 222. The bottom electrode spacer layer may be formed of silicon nitride. The bottom electrode spacer layer may be anisotropically etched to form bottom electrode spacers 222c and 222f on sidewalls of the intermediate contact holes 226c and 226f. The bottom electrode spacers 222c and 222f may include a cell bottom electrode spacer 222c formed at the cell region A and a fuse electrode spacer 222f formed at the fuse region B.

A bottom electrode layer (not shown) is deposited to fill the intermediate contact holes 226c and 226f. The substrate 200 may be planarized down to a top surface of the first intermediate interlayer dielectric 220 to form bottom electrodes 224c and 224f, which may include a cell bottom electrode 224c and a fuse bottom electrode 224f.

Referring to FIG. 7D, a top interlayer dielectric 240 may be formed on the top electrodes 224c and 224f. The top interlayer dielectric 240 may be formed of silicon oxide. The top interlayer dielectric 140 may be patterned down to top surfaces of the bottom electrodes 224c and 224f to form phase change contact holes 236c and 236f, which may include a cell phase change contact hole 236c formed at the cell region A and a fuse phase change contact hole 236f formed at the fuse region B.

A phase change spacer layer (not shown) may be conformally formed on the phase change contact holes 236c and 236f and the top interlayer dielectric 240. The phase change spacer layer may be anisotropically etched to form phase change spacers 231c and 231f on sidewalls of the phase change contact holes 236c and 236f. The phase change spacers 231c and 231f may include a cell phase change spacer 231c formed at the cell region A and a fuse phase change spacer 231f formed at the fuse region B. Each of the phase change spacers 231c and 231f may be formed of silicon nitride. A first phase change layer 232 may be conformally formed on the substrate 200 where the phase change spacers 231c and 231f are formed.

In an alternative embodiment, each of the phase change contact holes 236c and 236f may have the shape of a trench. The phase change spacers 231c and 231f may be formed on the sidewall of the trench.

Referring to FIG. 7E, the first phase change layer 232 at the cell region A may be removed, which may be done by means of anisotropic etching. A second phase change layer 234 may be deposited on the substrate 200 to fill the phase change contact holes 236c and 236f.

Referring to FIG. 7F, the substrate 200 including the deposited second phase change layer 234 may be planarized down to a top surface of the top interlayer dielectric 240 to form top phase change patterns 230c and 230f, which may include a cell top phase change pattern 230c formed at the cell region A and a fuse top phase change pattern 230f formed at the fuse region B. The fuse phase change pattern 230f may include a first fuse phase change pattern 232f and a second phase change pattern 234f.

In an alternative embodiment, phase change patterns 230c and 230f may be line-shaped phase change patterns filling the trench-shaped phase change contact holes 236c and 236f, respectively.

Returning to FIG. 2, a top interconnection layer (not shown) may be formed on the phase change patterns 230c and 230f. The top interconnection layer may be patterned to form top interconnections 260c and 260f, which may include a cell top interconnection 260c formed at the cell region A and a fuse top interconnection 260f formed at the fuse region B. Each of the cell top interconnection 260c and the fuse top interconnection 260f may have a multi-layer structure including a diffusion barrier layer 262, an interconnection layer 264, and a diffusion barrier layer 266 which are sequentially stacked.

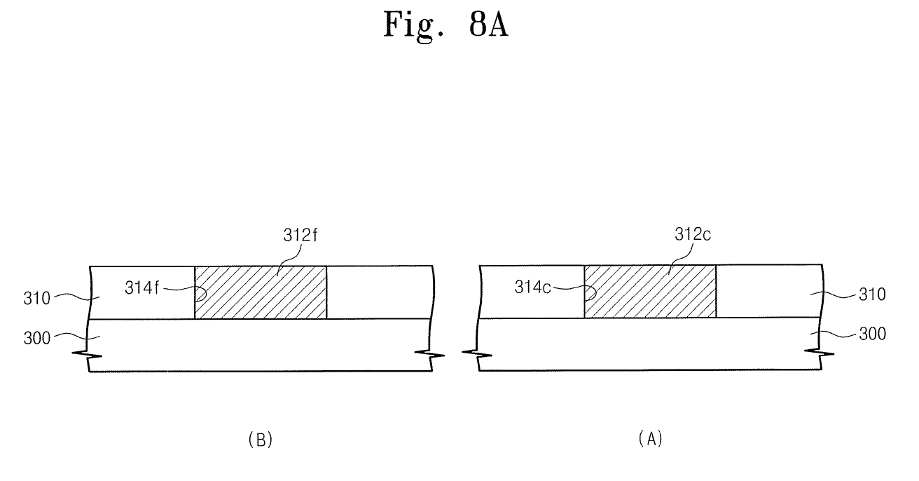

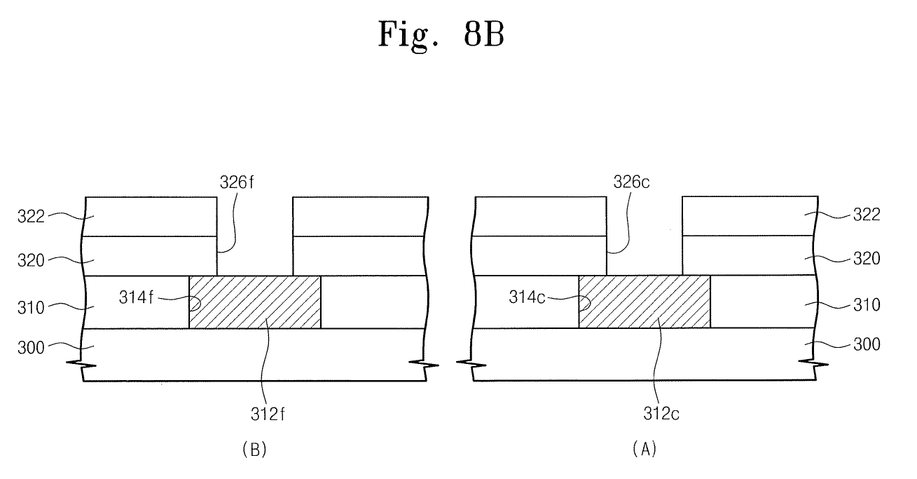

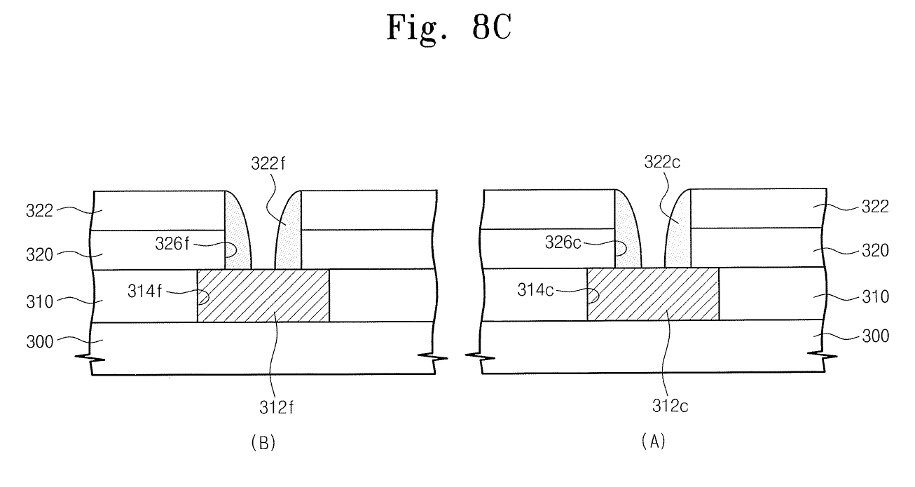

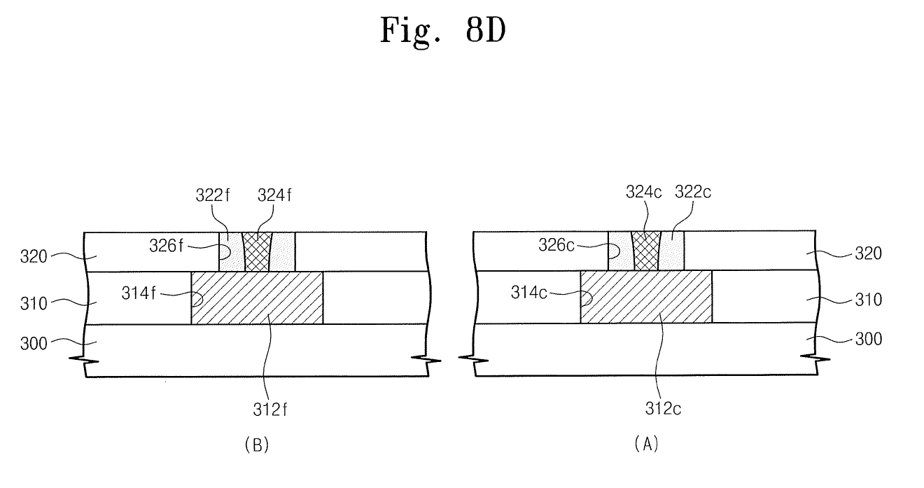

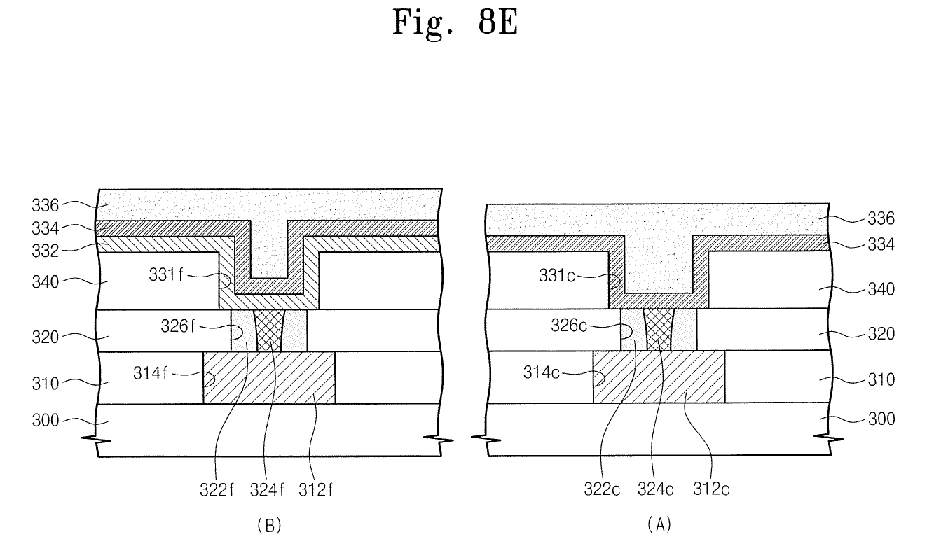

FIGS. 8A through 8E are cross-sectional views illustrating a method of forming an electric device according to yet another embodiment of the present invention.

Referring to FIG. 8A, a substrate 300 may include a fuse region A and a cell region B. A bottom interlayer dielectric 310 is formed on the substrate 300. The bottom interlayer dielectric 310 may be formed by means of chemical vapor deposition (CVD) or spin coating. The bottom interlayer dielectric 310 may be formed of silicon oxide. A top surface of the bottom interlayer dielectric 310 may be planarized. The bottom interlayer dielectric 310 may be patterned to form bottom contact holes 314c and 314f, which may include a cell bottom contact hole 314c formed at the cell region A and a fuse bottom contact hole 314f formed at the fuse region B. The cell contact hole 314c and the fuse contact hole 314f may be formed at the same time. A bottom interconnection layer (not shown) may be deposited to cover the bottom contact holes 314c and 314f and the bottom interlayer dielectric 310. The substrate 300 including the deposited bottom interconnection layer may be planarized to form bottom interconnections 312c and 312f, which may include a cell bottom interconnection 312c formed at the cell region A and a fuse bottom interconnection 312f formed at the fuse region B. The planarization of the substrate 300 including the deposited bottom interconnection layer may be done by means of a chemical mechanical polishing (CMP) process or an etch-back process.

Referring to FIG. 8B, a first intermediate interlayer dielectric 320 and a second intermediate interlayer dielectric 322 may be sequentially stacked on the bottom interconnections 314f and 314c and the bottom interlayer dielectric 310. The first intermediate interlayer dielectric 320 may be formed of silicon oxide, and the second intermediate interlayer dielectric 322 may be formed of silicon nitride or silicon oxynitride. By patterning the second and first intermediate interlayer dielectrics 322 and 320, intermediate contact holes 326c and 326f may be formed to expose the bottom interconnections 312c and 312f, respectively. The intermediate interlayer contact holes 326c and 326f may include a cell intermediate contact hole 326c formed at the cell region A and a fuse intermediate contact hole 326f formed at the fuse region B.

Referring to FIG. 8C, a bottom electrode spacer layer (not shown) may be conformally formed on the interlayer contact holes 326c and 326f and the second intermediate interlayer dielectric 322. The bottom electrode spacer layer may be formed of silicon nitride. The bottom electrode spacer layer may be anisotropically etched to form bottom electrode spacers 322c and 322f on sidewalls of the intermediate contact holes 326c and 326f. The bottom electrode spacers 322c and 322f may include a cell bottom electrode spacer 322c formed at the cell region A and a fuse electrode spacer 322f formed at the fuse region B.

Referring to FIG. 8D, a bottom electrode layer (not shown) may be deposited to fill the intermediate contact holes 326c and 326f. The substrate 300 may be planarized down to a top surface of the first intermediate interlayer dielectric 320 to form bottom electrodes 324c and 324f, which may include a cell bottom electrode 324c formed at the cell region A and a fuse bottom electrode 324f formed at the fuse region B.

Referring to FIG. 8E, a top interlayer dielectric 340 may be formed on the bottom electrodes 324c and 324f. The top interlayer dielectric 340 may be formed of silicon oxide. The top interlayer dielectric 340 may be patterned down to top surfaces of the bottom electrodes 324c and 324f to form phase change contact holes 331c and 331f. The first phase change layer 332 may be conformally formed on the phase change contact holes 331c and 331f and the top interlayer dielectric 340. The first phase change layer 331 at the cell region A may be removed by means of anisotropic etching. A second phase change layer 334 may be conformally formed on the phase change contact holes 331c and 331f and the top interlayer dielectric 340. The second phase change layer 334 may not fill up the phase change contact holes 331c and 331f. A top electrode layer 336 may be formed on the second phase change layer 334. In an alternative embodiment, each of the phase change contact holes 331c and 331f may have the shape of a trench.

Returning to FIG. 3, the substrate 300 may be planarized down to a top surface of the top interlayer dielectric 340 to form phase change patterns 330c and 330f and top electrodes 336c and 336f. The phase change patterns 330c and 330f may include a cell phase change pattern 33c formed at the cell region A and a fuse phase change pattern 330f formed at the fuse region B. The fuse phase change pattern 330f may include a first phase change pattern 332f and a second phase change pattern 334f. A top interconnection layer (not shown) may be formed on the phase change patterns 330c and/or the top electrodes 336c and 336f. The top interlayer connection layer may be patterned to form top interconnections 360c and 360f, which may include a cell top interconnection 360c formed at the cell region A and a fuse top interconnection 360f formed at the fuse region B. Each of the cell top interconnection 360c and the fuse top interconnection 360f may have a multi-layer structure including a diffusion barrier layer 362, an interconnection layer 364, and a diffusion barrier layer 366 which are sequentially stacked. In an alternative embodiment, the phase change patterns 330c and 330f may be a line-shaped patterns filling the trench-shaped phase change contact holes 331c and 331f, respectively.

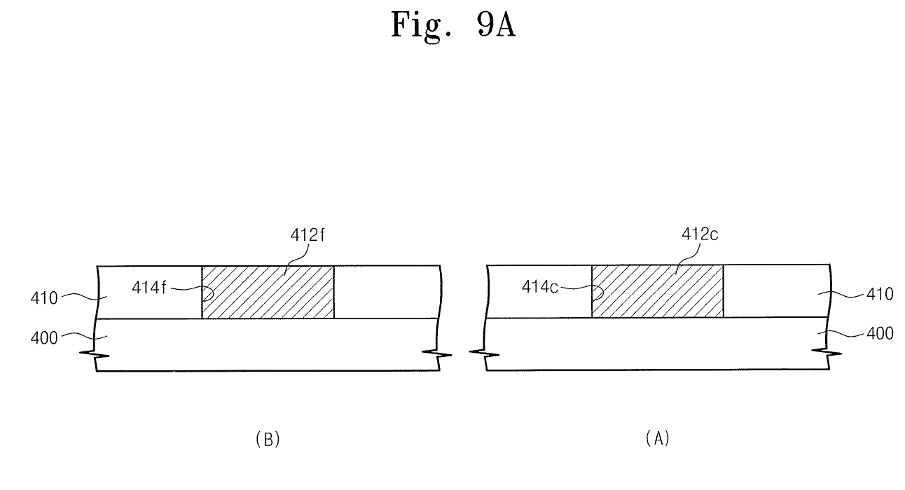

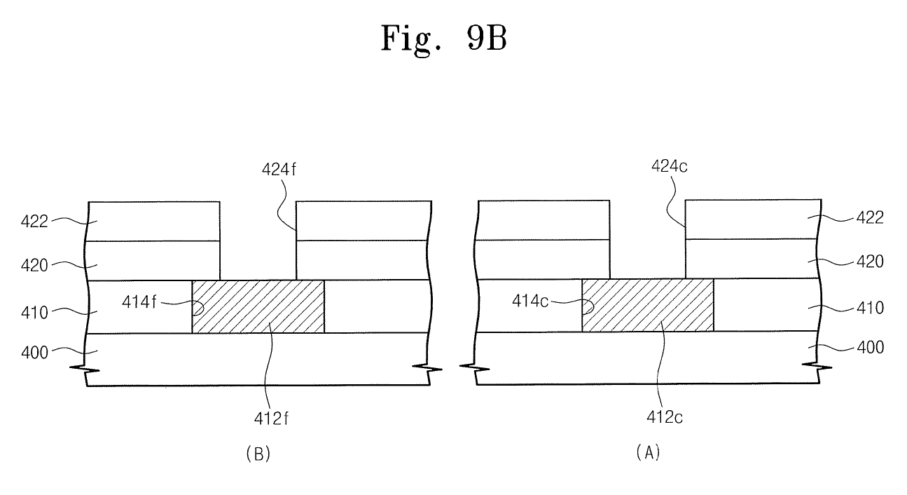

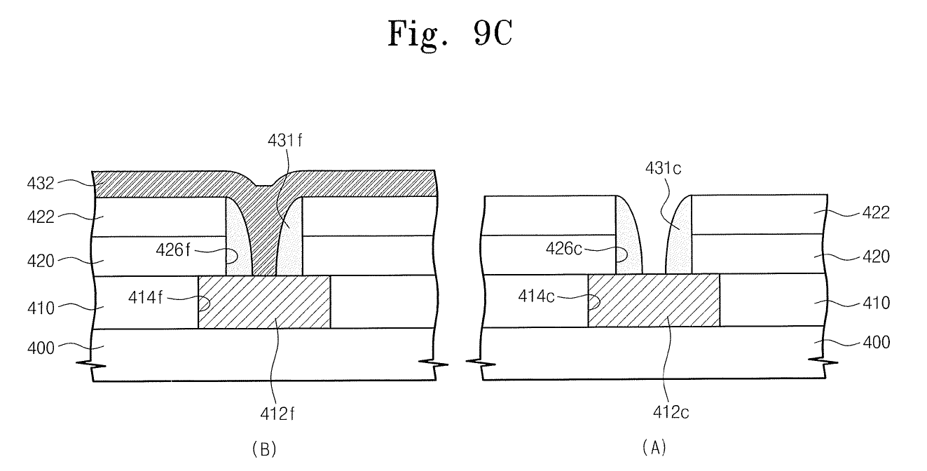

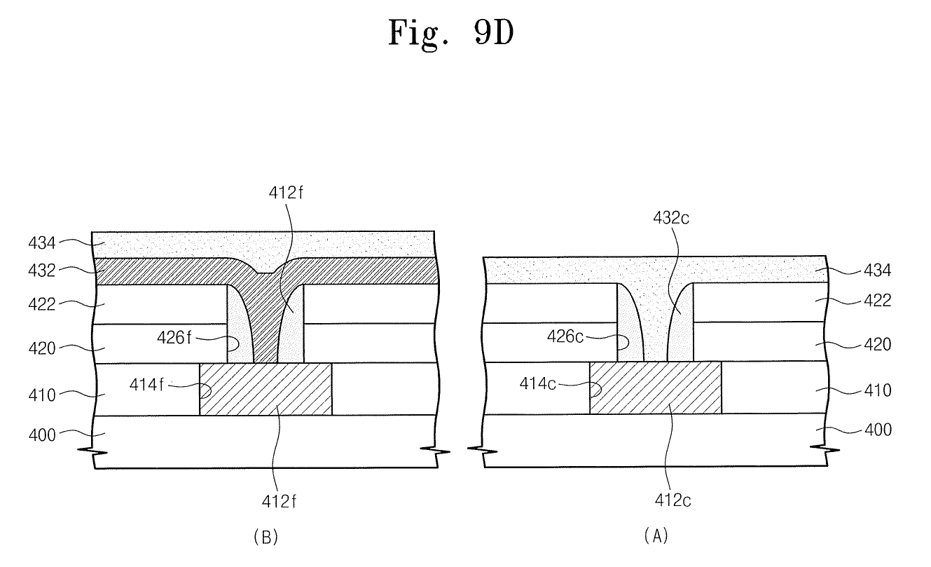

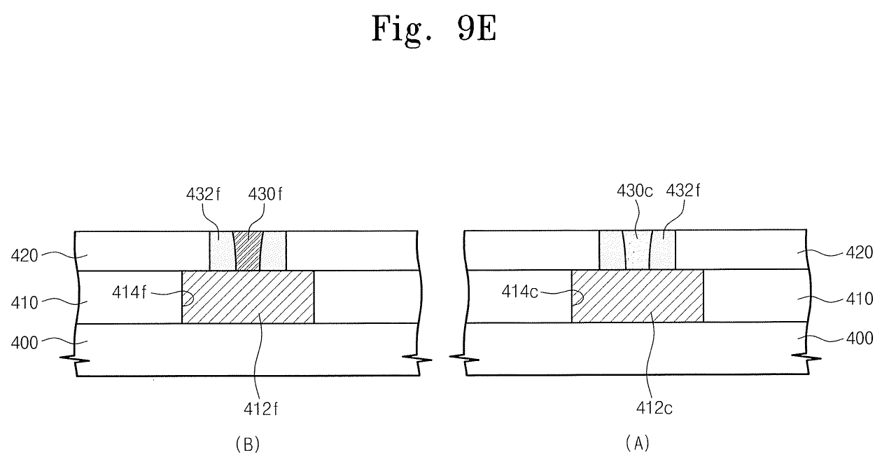

FIGS. 9A through 9E are cross-sectional views illustrating a method of forming an electric device according to further another embodiment of the present invention.

Referring to FIG. 9A, a substrate 400 may include a fuse region A and a cell region B. A bottom interlayer dielectric 410 is formed on the substrate 400. The bottom interlayer dielectric 410 may be formed by means of chemical vapor deposition (CVD) or spin coating. The bottom interlayer dielectric 410 may be formed of silicon oxide. A top surface of the bottom interlayer dielectric 410 may be planarized. The bottom interlayer dielectric 410 may be patterned to form bottom contact holes 414c and 414f, which may include a cell bottom contact hole 414c formed at the cell region A and a fuse bottom contact hole 414f formed at the fuse region B. The cell contact hole 414c and the fuse contact hole 414f may be formed at the same time. A bottom interconnection layer (not shown) may be deposited to cover the bottom contact holes 414c and 414f and the bottom interlayer dielectric 410. The substrate 400 including the deposited bottom interconnection layer may be planarized to form bottom interconnections 412c and 412f, which may include a cell bottom interconnection 412c formed at the cell region A and a fuse bottom interconnection 412f formed at the fuse region B. The planarization of the substrate 400 including the deposited bottom interconnection layer may be done by means of a chemical mechanical polishing (CMP) process or an etch-back process.

Referring to FIG. 9B, a first intermediate interlayer dielectric 420 and a second intermediate interlayer dielectric 422 may be sequentially stacked on the bottom interconnections 414f and 414c and the bottom interlayer dielectric 410. The first intermediate interlayer dielectric 420 may be formed of silicon oxide, and the second intermediate interlayer dielectric 422 may be formed of silicon nitride or silicon oxynitride. By patterning the second and first intermediate interlayer dielectrics 422 and 420, intermediate contact holes 424c and 424f may be formed to expose the bottom interconnections 412c and 412f, respectively. The intermediate interlayer contact holes 424c and 424f may include a cell intermediate contact hole 424c formed at the cell region A and a fuse intermediate contact hole 424f formed at the fuse region B.

Referring to FIG. 9C, a phase change spacer layer (not shown) may be conformally formed on the intermediate contact holes 424c and 424f and the second intermediate interlayer dielectric 422. The phase change spacer layer may be formed of silicon nitride. The phase change spacer layer may be anisotropically etched to form phase change spacers 431c and 431f at sidewalls of the intermediate contact holes 424c and 424f. The phase change spacers 431c and 431f may include a cell phase change spacer 431c formed at the cell region A and a fuse phase change spacer 431f formed at the fuse region B.

Referring to FIG. 9D, a first phase change layer 432 may be formed to fill the intermediate contact holes 424c and 424f. The first phase change layer 432 at the cell region A may be removed by means of anisotropic etching. A second phase change layer 434 may be formed on the substrate 400 to fill the cell intermediate contact hole 424c.

Referring to FIG. 9E, the substrate 400 may be planarized down to a top surface of the first intermediate interlayer dielectric 420 to form a cell phase change pattern 430c at the cell region A and a fuse phase change pattern 430f at the fuse region B. A crystallization temperature of the fuse phase change pattern 430f may be higher than that of the fuse phase change pattern 430c. The fuse phase change pattern 430f may be made of Ge₂Sb₂Te₅. The cell phase change pattern 430c may include one selected from the group consisting of As—Sb—Te-metal compound, As—Ge—Sb—Te-metal compound, metal-Sb—Te-metal compound, 5A group element-Sb—Te-metal compound, 6A group element-Sb—Te-metal compound, 5A group element-Sb—Se-metal compound, and 6A group element-Sb—Se-metal compound. There may be various ratios of the compounds. Specifically, the 5A group element may be nitrogen (N) or phosphorous (P), and the 6A group element may be oxygen (O) or sulfur (S). The fuse phase change pattern 430f may include at least one selected from the group consisting of In—Sb—Te, 5A group element-In—Sb—Te compound, and 6A group element-In—Sb—Te compound.

Returning to FIG. 4, a top interconnection layer may be formed on the phase change patterns 430c and 430f. The top interconnection layer may be patterned to form top interconnections 460c and 460f, which may include a cell top interconnection 460c formed at the cell region A and a fuse top interconnection 460f formed at the fuse region B. Each of the cell top interconnection 460c and the fuse top interconnection 460f may have a multi-layer structure including a diffusion barrier layer 462, an interconnection layer 464, and a diffusion barrier layer 466 which are sequentially stacked.

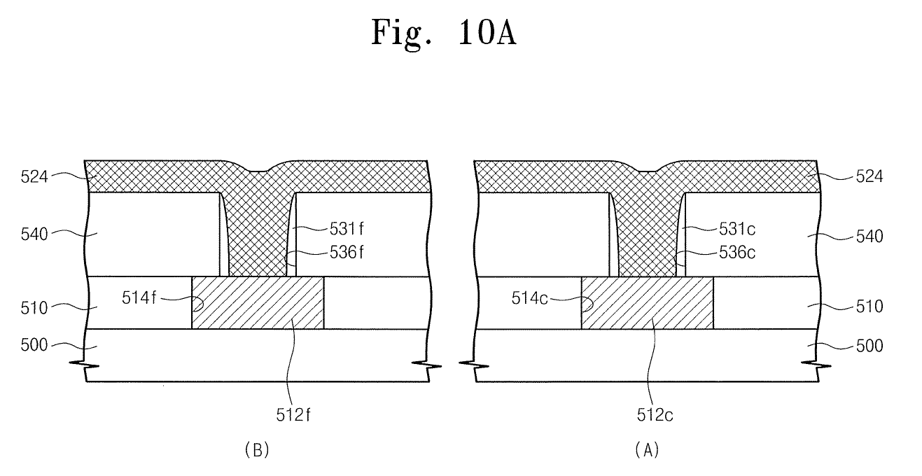

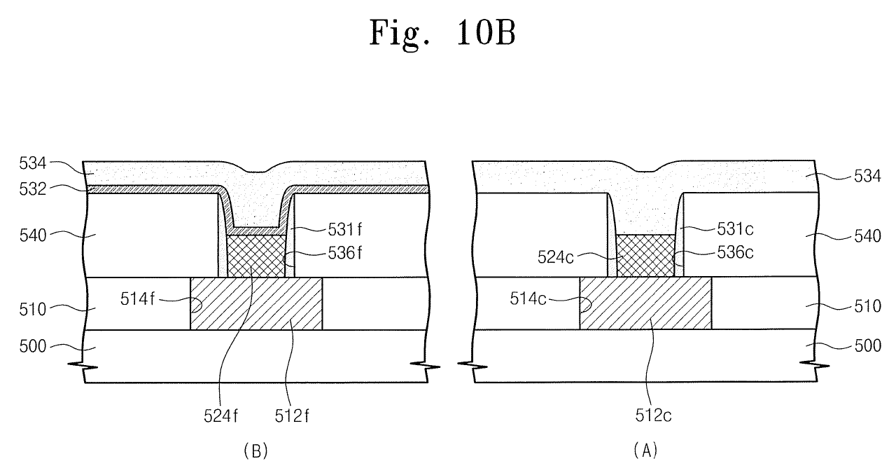

FIGS. 10A and 10B are cross-sectional views illustrating a method of forming an electric device according to still another embodiment of the present invention.

Referring to FIG. 10A, a substrate 500 may include a fuse region A and a cell region B. A bottom interlayer dielectric 510 is formed on the substrate 500. The bottom interlayer dielectric 510 may be formed by means of chemical vapor deposition (CVD) or spin coating. The bottom interlayer dielectric 510 may be formed of silicon oxide. A top surface of the bottom interlayer dielectric 510 may be planarized. The bottom interlayer dielectric 510 may be patterned to form bottom contact holes 514c and 514f, which may include a cell bottom contact hole 514c formed at the cell region A and a fuse bottom contact hole 514f formed at the fuse region B. The cell contact hole 514c and the fuse contact hole 514f may be formed at the same time. A bottom interconnection layer (not shown) may be deposited to cover the bottom contact holes 514c and 514f and the bottom interlayer dielectric 510. The substrate 500 including the deposited bottom interconnection layer may be planarized to form bottom interconnections 512c and 512f, which may include a cell bottom interconnection 512c formed at the cell region A and a fuse bottom interconnection 512f formed at the fuse region B. The planarization of the substrate 500 including the deposited bottom interconnection layer may be done by means of a chemical mechanical polishing (CMP) process or an etch-back process.

A top interlayer dielectric 540 may be formed on the bottom interlayer dielectric 510. The top interlayer dielectric 540 may be patterned down to top surfaces of the bottom interconnections 512c and 512f to form phase change contact holes 536c and 536f. A phase change spacer layer (not shown) may be conformally formed on the phase change contact holes 536c and 536f and the top interlayer dielectric 540. The phase change spacer layer may be anisotropically etched to form phase change spacers 531c and 531f on sidewalls of the phase change contact holes 536c and 536f. A bottom electrode layer 524 may be deposited to fill the phase change contact holes 536c and 536f. In an alternative embodiment, each of the phase change contact holes 536c and 536f may have the shape of a trench.

Referring to FIG. 10B, the bottom electrode layer may be etched back to form bottom electrodes 524c and 524f, which may include a cell bottom electrode 524c formed at the cell region A and a fuse bottom electrode 524f formed at the fuse region B. Top surfaces of the bottom electrodes 524c and 524f may be lower than a top surface of the top interlayer dielectric 540. A first phase change layer 532 may be deposited on the phase change contact holes 536c and 536f and the top interlayer dielectric 540. The first phase change layer 532 may be patterned to remove the first phase change layer 532 at the cell region A. The patterning of the first phase change layer 532 may include isotropic etching. A second phase change layer 534 may be deposited to fill the phase change contact holes 536c and 536f. A crystallization temperature of the first phase change layer 532 may be higher than that of the second phase change layer 534.

Returning to FIG. 5, the second phase change layer 534 and the first phase change layer 532 may be planarized down to a top surface of the top interlayer dielectric 540 to form a cell phase change pattern 530c at the cell region A and a fuse phase change pattern 530f at the fuse region B. The planarization of the second phase change layer 534 and the first phase change layer 532 may be done by means of chemical mechanical polishing (CMP). The fuse phase change pattern 530c may include a first fuse phase change pattern 532c and a second fuse phase change pattern 534c. In an alternative embodiment, the phase change patterns 530c and 530f may be line-shaped patterns filling the trench-shaped phase change contact holes 536c and 536f, respectively.

A top interconnection layer may be formed on the phase change patterns 530c and 530f. The top interconnection layer may be patterned to form top interconnections 560c and 560f, which may include a cell top interconnection 560c formed at the cell region A and a fuse top interconnection formed at the fuse region B. The cell top interconnection 560c may have a multi-layer structure including a diffusion barrier layer 562c, an interconnection layer 564c, and a diffusion barrier layer 566c which are sequentially stacked, and the fuse top interconnection 560f may have a multi-layer structure including a diffusion barrier layer 562f, an interconnection layer 564f, and a diffusion barrier layer 566f which are sequentially stacked.

Although the present invention has been described in connection with the embodiment of the present invention illustrated in the accompanying drawings, it is not limited thereto. It will be apparent to those skilled in the art that various substitutions, modifications and changes may be made without departing from the scope and spirit of the invention.

1. A non-volatile memory device, comprising:
an array of phase-changeable memory cells comprising first phase-changeable material patterns therein; and
at least one phase-changeable fuse element having a second phase-changeable material pattern therein with a higher crystallization temperature relative to the first phase-changeable material patterns in said array of phase-changeable memory cells.

2. The memory device of claim 1, wherein said at least one phase-changeable fuse element comprises a composite of the second phase-changeable material pattern and a third phase-changeable material pattern comprising the same material at the first phase-changeable material patterns.

3. The memory device of claim 2, wherein the second phase-changeable material pattern is in contact with the third phase-changeable material pattern.

4. The memory device of claim 1, wherein the second phase-changeable material pattern has a U-shaped cross-section; and wherein a recess in the second phase-changeable material pattern is filled with the third phase-changeable material pattern.

5. The memory device of claim 1, wherein the second phase-changeable material pattern has a crystallization temperature of greater than about 300° C.

6. An integrated circuit device, comprising:
a phase-changeable fuse element comprising at least two different phase-changeable materials having unequal crystallization temperatures.

7. The device of claim 6, further comprising a phase-changeable memory cell devoid of one of the at least two different phase-changeable memory cells having a higher crystallization temperature.

8. The device of claim 6, wherein a first one of the at least two different phase-changeable materials has a recess therein at least partially filed by a second one of the at least two different phase-changeable materials.

9. The device of claim 8, wherein the first one of the at least two different phase-changeable materials has a higher crystallization temperature relative to the second one of the at least two different phase-changeable materials.

10. The device of claim 9, wherein said phase-changeable memory cell comprises the second one of the at least two different phase-changeable materials.

11. A non-volatile memory device, comprising:
an array of non-volatile memory cells; and
a phase-changeable fuse element having a phase-changeable material therein with a crystallization temperature of greater than about 300° C.

12. The device of claim 11, wherein the non-volatile memory cells in said array are phase-changeable memory cells.

13. The device of claim 11, wherein the non-volatile memory cells in said array are phase-changeable memory cells that comprise phase-changeable materials having a crystallization temperature less than 300° C.

14. An electric device comprising:
a bottom interconnection disposed on a substrate;
a first phase change pattern disposed on the bottom interconnection;
a second phase change pattern disposed on the first phase change pattern; and
a top interconnection disposed on the first and second phase change patterns,
wherein a crystallization temperature of the first phase change pattern is higher than that of the second phase change pattern.

15. The electric device of claim 14, further comprising:
a bottom electrode interposed between the bottom interconnection and the first phase change pattern.

16. The electric device of claim 15, further comprising:
a spacer disposed on the sidewall of the bottom electrode.

17. The electric device of claim 14, further comprising:
a top electrode interposed between the second phase change pattern and the top interconnection.

18. The electric device of claim 17, further comprising:
a top interconnection contact plug disposed between the top electrode and the top interconnection.

19. The electric device of claim 17, wherein the first phase change pattern is a pot-shaped or concave line-shaped pattern, the second phase change pattern is a pot-shaped or a concave line-shaped pattern disposed in the first phase change pattern, and the top electrode is shaped to fill the inside of the second phase change pattern.

20. The electric device of claim 14, wherein side surfaces of the first and second phase change patterns are aligned to each other.

21.-33. (canceled)
